(19) United States
(12) Patent Application Publication
(10) Pub. No.: US 2015/0221614 A1
(43) Pub. Date: Aug. 6, 2015

(54) HIGH-BANDWIDTH DRAM USING INTERPOSER AND STACKING

(71) Applicant: Sehat Sutardja, Los Altos Hills, CA (US)

(72) Inventor: Sehat Sutardja, Los Altos Hills, CA (US)

(21) Appl. No.: 14/615,317

(22) Filed: Feb. 5, 2015

Related U.S. Application Data
(60) Provisional application No. 61/936,800, filed on Feb. 6, 2014.
(60) Provisional application No. 61/937,340, filed on Feb. 7, 2014.

(51) Int. Cl. H01L 25/065; H01L 23/31; H01L 23/367; H01L 23/498

(52) U.S. Cl. CPC H01L 25/0657; H01L 23/49822; H01L 23/3107; H01L 23/3675; H01L 2225/0651; H01L 2225/06562; H01L 2225/06589; H01L 2225/06586

(57) ABSTRACT

Embodiments of the present disclosure provide a packaging arrangement that comprises an interposer and a system on chip (SoC) die disposed on the interposer. The packaging arrangement also comprises a plurality of memory dies stacked on one another to provide a stack of memory dies. A bottom memory die of the stack of memory dies is disposed on the substrate adjacent to the SoC die. Each memory die includes input/output (I/O) pads, wherein the I/O pads of a corresponding memory die are located on only one side of the corresponding memory die. The plurality of memory dies is stacked on one another such that all of the I/O pads are arranged along a same side of the stack of memory dies. The plurality of memory dies is also stacked such that all the I/O pads are exposed.

### CROSS REFERENCE TO RELATED APPLICATIONS

This claims priority to U.S. Provisional Patent Application No. 61/936,800, filed Feb. 6, 2014, and to U.S. Provisional Patent Application No. 61/937,340, filed Feb. 7, 2014, the entire specifications of which are hereby incorporated by reference in their entireties.

### TECHNICAL FIELD

Embodiments of the present disclosure relate to semiconductor packages, and more particularly, to semiconductor packages that include high-bandwidth dynamic random access memories (DRAM) where the DRAMs are stacked in a staggered relationship.

### BACKGROUND

As higher performance electronic systems are implemented, higher-bandwidth dynamic random access memory (DRAM) that is cost effective is needed. While there have been many proposals and sample devices from the DRAM industry, such as, for example, Wide-I/O2, HBM (High-Bandwidth Memory) and HMC (Hybrid Memory Cube), in order to provide higher bandwidth such proposals require expensive technology such as, for example, through-silicon vias (TSV) and thus may not be appropriate for low-cost electronic systems. Additionally, pins to access such types of DRAM dies are usually located in the middle of the DRAM die and thus, the high-speed signal traces may be long. Also, because the footprint of the pins is large compared to a system-on-chip (SoC) die size, it may be difficult to stack the proposed types of DRAM dies without an interposer.

### SUMMARY

In various embodiments, the present disclosure provides a packaging arrangement that comprises an interposer and a system on chip (SoC) die disposed on the interposer. The packaging arrangement also comprises a plurality of memory dies stacked on one another to provide a stack of memory dies. A bottom memory die of the stack of memory dies is disposed on the interposer adjacent to the SoC die. Each memory die includes input/output (I/O) pads, wherein the I/O pads of a corresponding memory die are located on only one side of the corresponding memory die. The plurality of memory dies is stacked on one another such that all of the I/O pads are arranged along a same side of the stack of memory dies. The plurality of memory dies is also stacked such that all the I/O pads are exposed.

In various embodiments, the present disclosure provides a packaging arrangement comprising an interposer and a plurality of memory dies stacked on one another to provide a stack of memory dies. A bottom memory die of the stack of memory dies is disposed on the interposer. Each memory die includes input/output (I/O) pads. The I/O pads of a corresponding memory die are located on only one side of the corresponding memory die. The plurality of memory dies is stacked on one another such that all of the I/O pads are arranged along a same side of the stack of memory dies. The plurality of memory dies is also stacked such that all the I/O pads are exposed.

### BRIEF DESCRIPTION OF THE DRAWINGS

Embodiments of the present disclosure will be readily understood by the following detailed description in conjunction with the accompanying drawings. To facilitate this description, like reference numerals designate like structural elements. Embodiments herein are illustrated by way of example and not by way of limitation in the figures of the accompanying drawings.

FIG. 1A is a side, cross-sectional schematic view of a packaging arrangement for stacked DRAM dies, in accordance with various embodiments.

FIG. 1B is a top view of the packaging arrangement illustrated in FIG. 1A, in accordance with various embodiments.

FIG. 1C is a side, cross-sectional schematic view of a second packaging arrangement for DRAM dies, in accordance with various embodiments.

FIG. 1D is a side, cross-sectional schematic view of a third packaging arrangement for DRAM dies, in accordance with various embodiments.

FIG. 1E is a side, cross-sectional schematic view of a fourth packaging arrangement for DRAM dies, in accordance with various embodiments.

FIGS. 2A and 2B are side cross-sectional schematic views of packaging arrangements that include the packaging arrangement of FIGS. 1A-1E in combination with a SoC die, in accordance with various embodiments.

FIG. 2C is a side, cross-sectional schematic view of a packaging arrangement that includes a packaging arrangement similar to the packaging arrangements illustrated in FIGS. 1A-1E in combination with a SoC die, in accordance with various embodiments.

FIG. 3 is a side, cross-sectional schematic view of an alternative packaging arrangement for stacked DRAM dies, in accordance with various embodiments.

### DETAILED DESCRIPTION

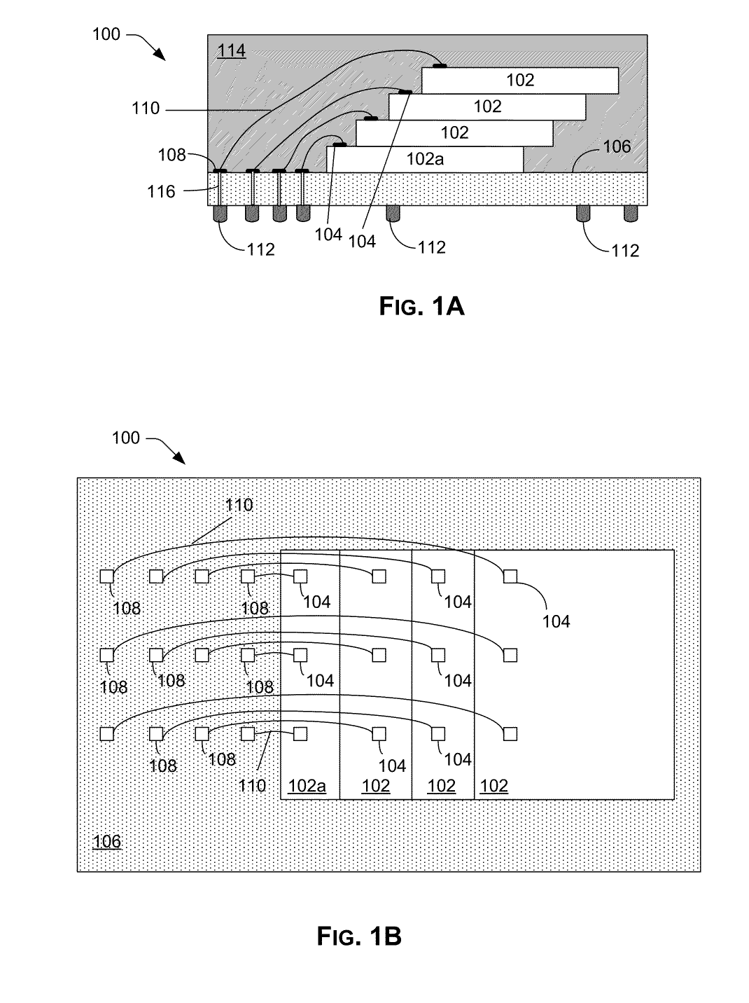

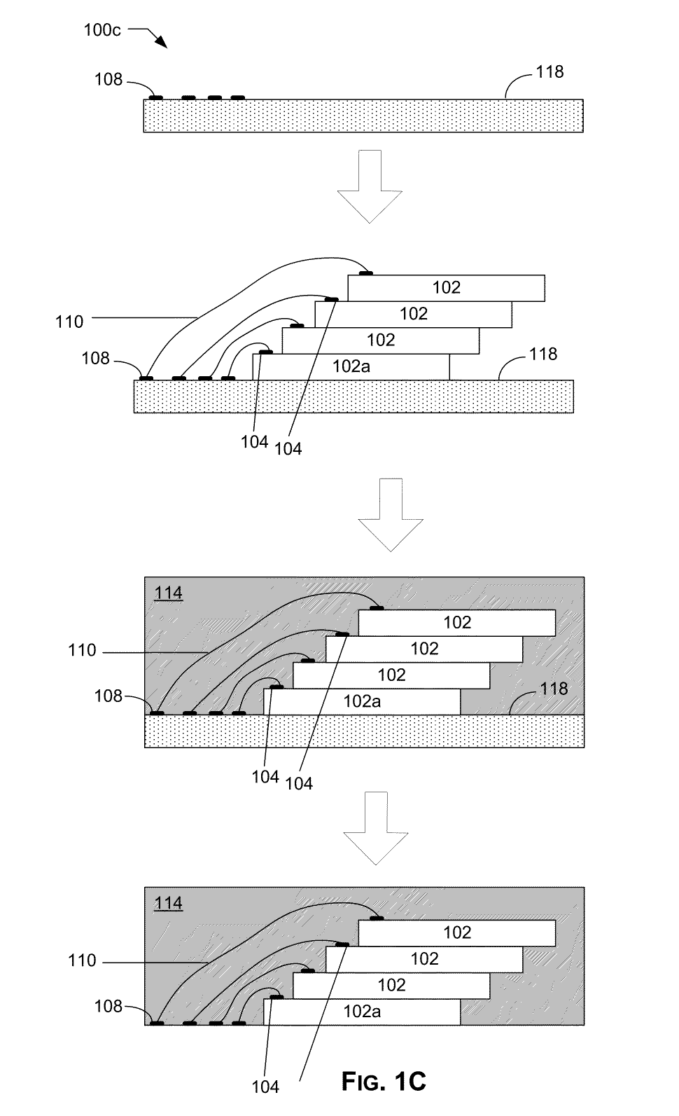

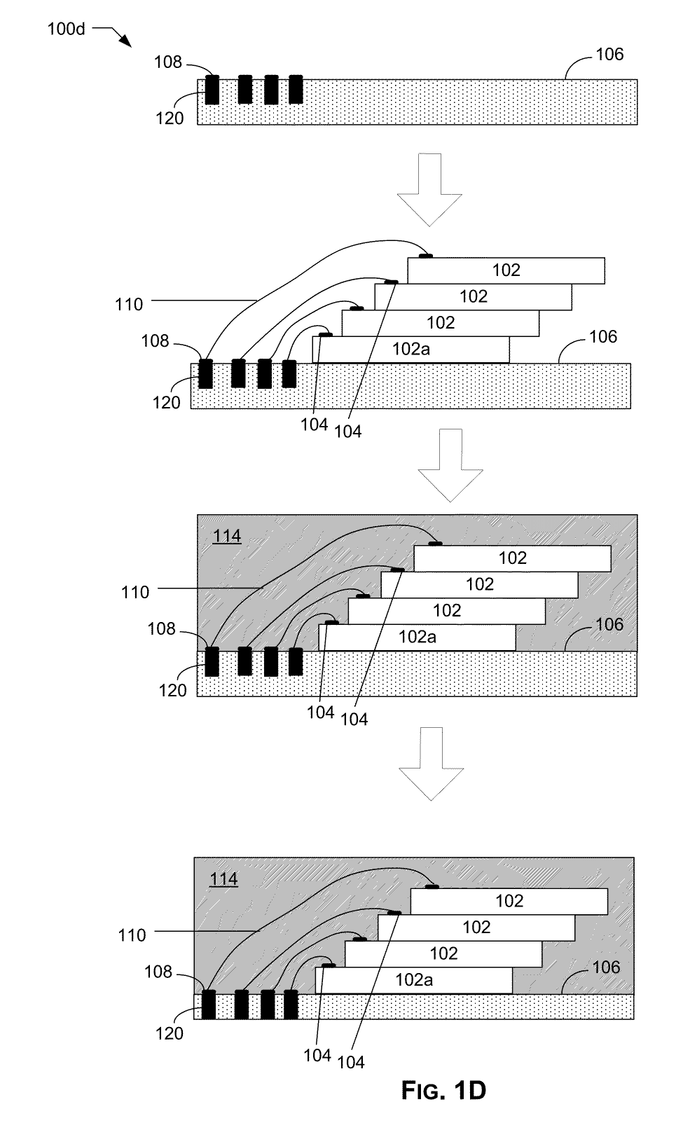

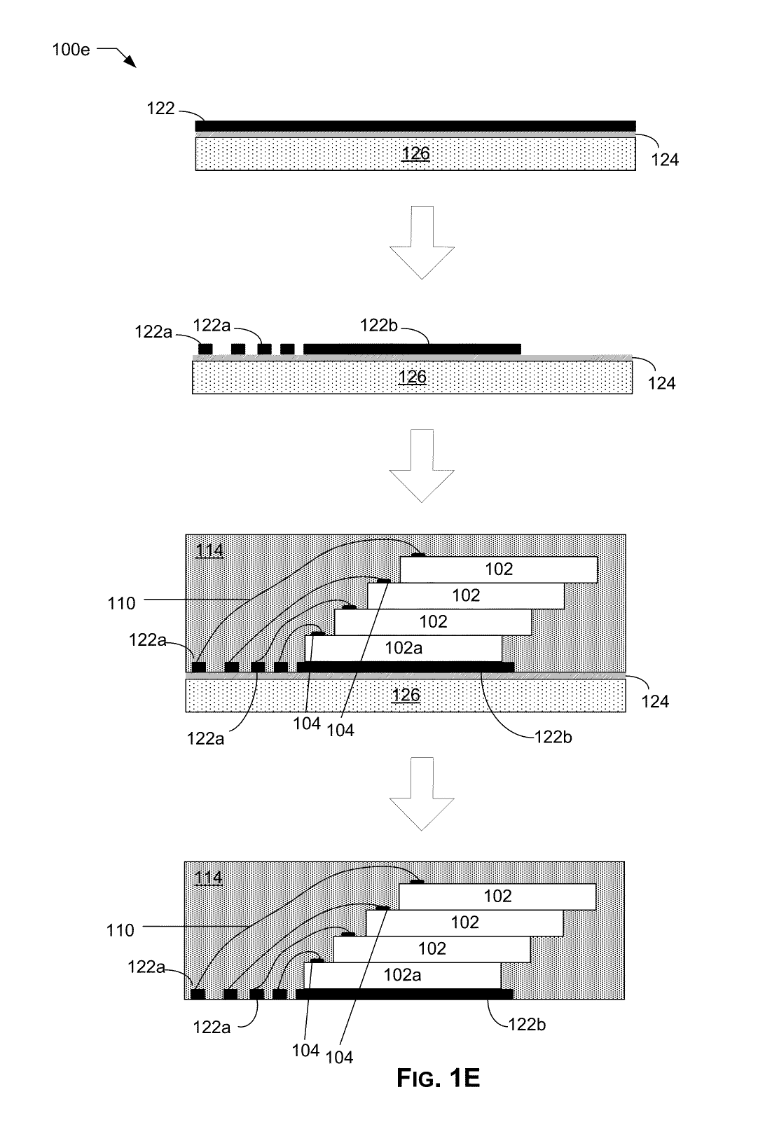

FIG. 1A illustrates a packaging arrangement for a memory die arrangement 100 for a plurality of memory dies 102. In accordance with various embodiments, the memory dies 102 comprise low power double data rate synchronous (LPDDR) dynamic random access memory (DRAM) dies. In accordance with various embodiments, the stack of memory dies 102 may include two to four memory dies 102. However, more memory dies 102 may be included depending upon the application. In accordance with various embodiments, the memory dies 102 comprise DRAM dies having a capacity of 1 gigabyte (GB), 2 GB, or 4 GB, and a 32-bit wide data bus. Higher and lower capacity memory dies may be utilized if desired. All memory dies 102 do not need to have the same capacity as other memory dies 102 in the memory die arrangement 100. Additionally, memory dies having a data bus width different than 32 bits may also be utilized if desired.

As can be seen in FIG. 1A, the memory dies 102 are stacked on one another in a staggered or offset relationship. The memory dies 102 may be coupled to each other using, for example, an adhesive, solder, etc. Each memory die 102 includes input/output (I/O) pads in the form of bond pads 104 located along one edge of a corresponding memory die 102. Thus, when the plurality of memory dies 102 is stacked in the offset relationship, all of the bond pads 104 are exposed. Additionally, the plurality of memory dies 102 is stacked such that all of the bond pads 104 are along a same edge of the stack of memory dies 102.

A bottom memory die 102a is disposed on an interposer or substrate 106. The interposer 106 may comprise glass, silicon, or any other suitable material. In accordance with various embodiments, glass is utilized for the interposer 106 since glass provides for a higher resolution that allows for finer line width and spacing as well as fine pitch pads. The glass interposer 106 may also cost less than a silicon or similar type material interposer. As can be seen, the bond pads 104 of the memory dies 102 are coupled to I/O pads in the form of bond pads 108 on the interposer 106 via wirebond connections 110. Coupling structures 112 in the form of, for example, copper pillars and/or solder balls are provided on a bottom surface of the interposer 106 to provide coupling between the memory die arrangement 100 and a substrate (not illustrated), such as, for example, a printed circuit board (PCB), a die, another packaging arrangement, etc. The interposer 106 includes, for example, various traces, vias, a redistribution layer (RDL), etc., to allow for electrical communication between the bond pads 108 of the interposer 106 and the coupling structures 112. FIG. 1A illustrates vias 116 as an example for providing electrical communication between the bond pads 108 and the coupling structures 112. A molding compound 114 is generally included over the stack of memory dies 102 in order to encapsulate the stack of memory dies 102 and the wirebond connections 110. The molding compound 114 generally comprises an encapsulant that is electrically insulating.

FIG. 1B is a top view of the memory die arrangement 100 illustrated in FIG. 1A. The memory die arrangement 100 in FIG. 1B does not include the molding compound 114 for clarity. Additionally, for clarity the wirebond connections 110 are illustrated slightly out of place for clarity, i.e. the wirebond connections 110 would generally extend in straight lines between the various bond pads 104, 108. As can be seen, all of the bond pads 104 of the memory dies 102 are located along one side of the stack of the memory dies 102. The bond pads 104 of the memory dies 102 are coupled to the bond pads 108 of the interposer 106 via the wirebond connections 110. As can be seen, such an arrangement can allow for shorter high-speed signal traces.

FIG. 1C illustrates another embodiment of a packaging arrangement for a memory die arrangement 100c of the stack of memory dies 102. In the embodiment of FIG. 1C, the arrangement 100c disposes bond pads 108 on a carrier 118 as opposed to on the interposer or substrate 106 of FIG. 1A. The memory dies 102 are stacked on the carrier 118 and wire bonds 110 couple the bond pads 104 of the memory dies 102 to the bond pads 108. A molding compound 114 is disposed over the stack of memory dies 102 in order to encapsulate the stack of memory dies 102 and the wire bond connections 110. The molding compound 114 generally comprises an encapsulant that is electrically insulating. The carrier 118 is then removed to thereby expose a surface of the bond pads 108 through the molding compound 114. The exposed surfaces of the bond pads 108 serve as contacts that can be utilized to electrically couple the arrangement 100c to another substrate (not illustrated) such as, for example, a PCB, another die, another packaging arrangement. In embodiments, the carrier 118 may comprise, for example, glass and thus, hydrofluoric acid may be used to remove the carrier 118. As other examples, the carrier 118 may comprise silicon, copper, etc., which may be removed via various processes such as, for example, etching, grinding, etc.

FIG. 1D illustrates another embodiment of a packaging arrangement for a memory die arrangement 100d of the stack of memory dies 102. In the embodiment of FIG. 1D, the arrangement 100d includes the interposer or substrate 106 of FIG. 1A. The interposer 106 comprises silicon and includes vias 120 prefabricated in the interposer 106. In embodiments, the vias 120 comprise a conductive material such as, for example, copper. The memory dies 102 are stacked on the interposer 106 and wire bonds 110 couple the bond pads 104 of the memory dies 102 to surfaces 108 of the vias 120. A molding compound 114 is disposed over the stack of memory dies 102 in order to encapsulate the stack of memory dies 102 and the wire bond connections 110. The molding compound 114 generally comprises an encapsulant that is electrically insulating. The interposer 106 is then back ground or etched to thereby expose a surface of the vias 120 through the molding compound 114. The exposed surfaces of the vias 120 serve as contacts that can be utilized to electrically couple the arrangement 100d to another substrate (not illustrated) such as, for example, a PCB, another die, another packaging arrangement.

FIG. 1E illustrates another embodiment of a packaging arrangement for a memory die arrangement 100e of the stack of memory dies 102. In the embodiment of FIG. 1e, the arrangement 100e includes a thin copper layer 122 that is coupled to a release layer 124. The release layer is also coupled to a carrier layer 126. Generally, the carrier layer 126 comprises copper, but may comprise other materials such as, for example, glass, silicon, etc. The thin copper layer 122 is etched to provide bond pads 122a and a larger copper portion 122b. Other bond pads (not illustrated) may be provided on the opposite side of copper portion 122b if desired. The memory dies 102 are stacked on the copper portion 122b and wire bonds 110 couple the bond pads 104 of the memory dies 102 to the bond pads 122a created from the thin copper layer 122. A molding compound 114 is disposed over the stack of memory dies 102 in order to encapsulate the stack of memory dies 102 and the wire bond connections 110. The molding compound 114 generally comprises an encapsulant that is electrically insulating. Upon completion of the packaging arrangement 100e, the carrier layer 126 is removed through an appropriate method. If the carrier layer 126 comprises copper, the removed carrier layer may be recycled. The release layer 124 is also removed to thereby expose a surface of the bond pads 122a through the molding compound 114. The exposed surfaces of the bond pads 122a serve as contacts that can be utilized to electrically couple the arrangement 100e to another substrate (not illustrated) such as, for example, a PCB, another die, another packaging arrangement. The copper portion 122b strengthens package integrity and may also act as a heat sink.

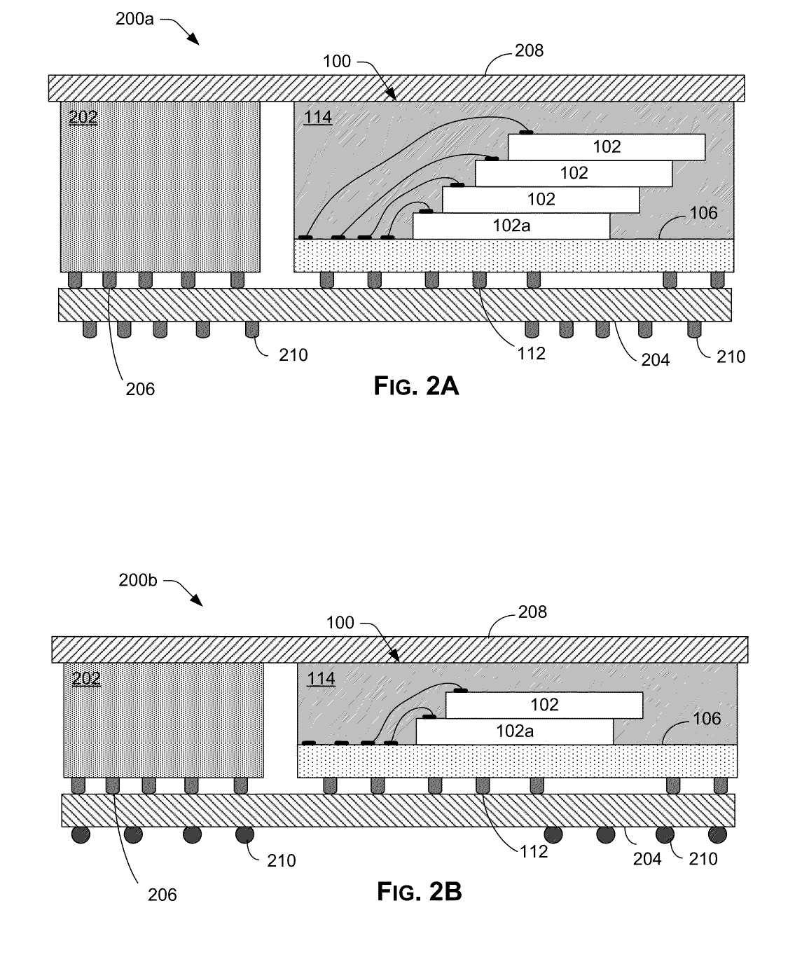

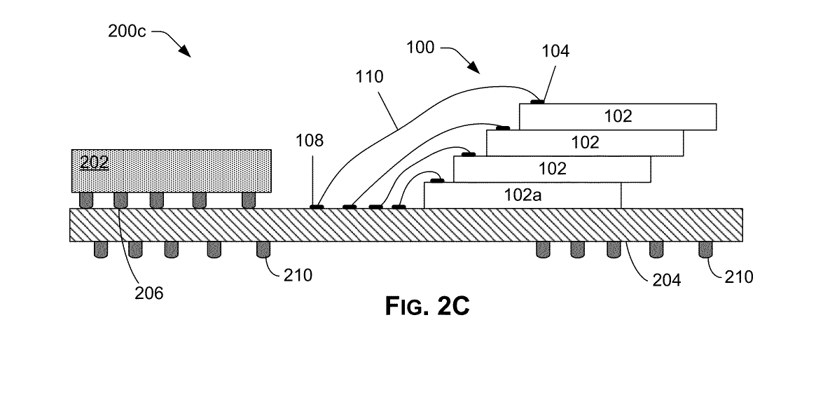

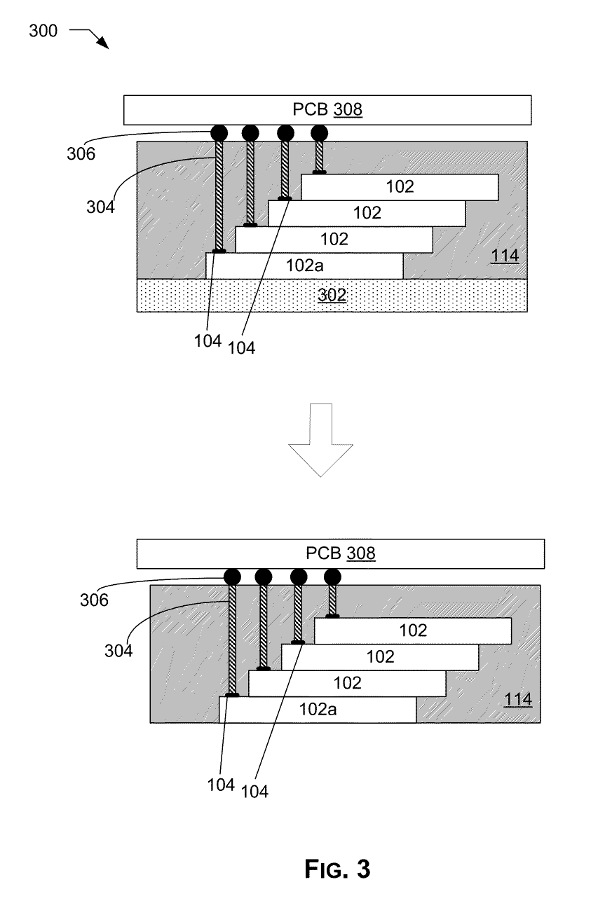

FIG. 2A illustrates a packaging arrangement 200a for utilizing the memory die arrangement 100 of FIGS. 1A and 1B in combination with a system-on-chip (SoC) die 202. The memory die arrangement 100 is coupled to a substrate 204 such as, for example, an interposer that may comprise glass, silicon or other suitable material. The substrate 204 may also be a multi-chip module substrate. The memory die arrangement 100 is coupled to the substrate via the coupling structures 112. The SoC die 202 is also coupled to the substrate via coupling structures 206 such as, for example, copper pillars and/or copper solder balls. The SoC die 202 and/or the packaging arrangement 100 may be flip chip attached to the substrate 204. A heat sink 208 may be coupled to the top of the SoC die 202 and the memory die arrangement 100. Coupling structures 210 such as, for example, copper pillars and/or copper solder balls are provided on a bottom surface of the substrate 204 to couple the packaging arrangement 200a to another substrate (not illustrated) such as, for example, a printed circuit board.

FIG. 2A illustrates an example of the packaging arrangement 200a wherein four memory dies 102 are provided. FIG. 2B illustrates an alternative embodiment of the packaging arrangement 200b wherein only two memory dies 102 are provided. The substrate 204 includes traces and/or vias to transmit signals within the substrate 204 from the coupling structures 206, 112 that couple the SoC die 202 and the memory die arrangement 100 to the substrate 204.

FIG. 2C illustrates an embodiment of a packaging arrangement 200c similar to the packaging arrangements 200a and 200b of FIGS. 2A and 2B. In the embodiment of FIG. 2C, the memory dies 102 are stacked directly on the substrate 204 and thus, the memory die arrangement 100 does not include a separate interposer 106. The bottom memory die 102a may be coupled to the substrate 204 with an adhesive or may be coupled to the substrate 204 using coupling structures (not illustrated) as previously described. A molding compound (not illustrated) may be included over the memory die arrangement 100 if desired to encapsulate the stack of memory dies 102 and the wirebond connections 110. The molding compound 114 generally comprises an encapsulant that is electrically insulating. Additionally, a heat sink (not illustrated) may be coupled to a top surface of the SoC die 202 and/or a top of the memory die arrangement 100.

FIG. 3 illustrates an alternative embodiment of a memory die arrangement 300 of the stack of memory dies 102. In the embodiment of FIG. 3, the arrangement 300 includes a carrier layer 302 upon which the memory dies 102 are stacked. The carrier layer 302 may be removed subsequently. Pillars 304 are created on the bond pads 104 of the memory dies 102. In various embodiments, the pillars comprise a conductive material such as, for example, copper. A molding compound 114 is generally included over the stack of memory dies 102 in order to encapsulate the stack of memory dies 102 and the pillars 304. The molding compound 114 is disposed such that surfaces of the pillars 304 are exposed through the molding compound 114. The exposure of the surfaces of the pillars 304 can be achieved by etching, grinding, etc., or by adding the molding compound 114 to the arrangement 300 such that surfaces of the pillars 304 remain exposed. The molding compound generally comprises an encapsulant that is electrically insulated. The exposed surfaces of the pillars 304 serve as contacts that can be utilized to electrically couple the arrangement 300 to another substrate such as, for example, a PCB 308, another die, another packaging arrangement. Solder balls 306 are provided to couple the packaging arrangement 300 to the PCB 308.

The description may use perspective-based descriptions such as up/down, over/under, and/or, or top/bottom. Such descriptions are merely used to facilitate the discussion and are not intended to restrict the application of embodiments described herein to any particular orientation.

For the purposes of the present disclosure, the phrase “A/B” means A or B. For the purposes of the present disclosure, the phrase “A and/or B” means “(A), (B), or (A and B).” For the purposes of the present disclosure, the phrase “at least one of A, B, and C” means “(A), (B), (C), (A and B), (A and C), (B and C), or (A, B and C).” For the purposes of the present disclosure, the phrase “(A)B” means “(B) or (AB)” that is, A is an optional element.

Various operations are described as multiple discrete operations in turn, in a manner that is most helpful in understanding the claimed subject matter. However, the order of description should not be construed as to imply that these operations are necessarily order-dependent. In particular, these operations may not be performed in the order of presentation. Operations described may be performed in a different order than the described embodiment. Various additional operations may be performed and/or described operations may be omitted in additional embodiments.

The description uses the phrases “in an embodiment,” “in embodiments,” or similar language, which may each refer to one or more of the same or different embodiments. Furthermore, the terms “comprising,” “including,” “having,” and the like, as used with respect to embodiments of the present disclosure, are synonymous.

The terms chip, die, semiconductor die, integrated circuit, monolithic device, semiconductor device, die, and microelectronic device are often used interchangeably in the microelectronics field. The present invention is applicable to all of the above as they are generally understood in the field.

Although certain embodiments have been illustrated and described herein, a wide variety of alternate and/or equivalent embodiments or implementations calculated to achieve the same purposes may be substituted for the embodiments illustrated and described without departing from the scope of the present disclosure. This disclosure is intended to cover any adaptations or variations of the embodiments discussed herein. Therefore, it is manifestly intended that embodiments described herein be limited only by the claims and the equivalents thereof.

What is claimed is:

1. A packaging arrangement comprising:
an interposer;
a system on chip (SoC) die disposed on the interposer;
a plurality of memory dies stacked on one another to provide a stack of memory dies, wherein a bottom memory die of the stack of memory dies is disposed on the interposer adjacent to the SoC die, wherein each memory die includes input/output (I/O) pads, wherein the I/O pads of a corresponding memory die are located on only one side of the corresponding memory die, wherein the plurality of memory dies is stacked on one another such that all of the I/O pads are arranged along a same side of the stack of memory dies, and wherein the plurality of memory dies is stacked such that all the I/O pads are exposed.

2. The packaging arrangement of claim 1, wherein the plurality of memory dies comprises a plurality of low power double data rate synchronous (LPDDR) dynamic random access memory (DRAM) dies.

3. The packaging arrangement of claim 2, wherein the I/O pads are located on top surfaces of the LPDDR DRAMs and the plurality of LPDDR DRAMs are stacked in an offset relationship such that all the I/O pads are exposed.

4. The packaging arrangement of claim 3, wherein the plurality of LPDDR DRAMs comprises four LPDDR DRAMs.

5. The packaging arrangement of claim 4, wherein:
the interposer is a first interposer;
the packaging arrangement comprises a second interposer; and
the bottom memory die is disposed on the second interposer and the second interposer is disposed on the first interposer.

6. The packaging arrangement of claim 5, further comprising a molding compound over the four LPDDR DRAMs.

7. The packaging arrangement of claim 6, further comprising a heat sink on the molding compound and the SoC die.

8. The packaging arrangement of claim 3, comprising two LPDDR DRAMs.

9. The packaging arrangement of claim 8, wherein:
the interposer is a first interposer;
the packaging arrangement comprises a second interposer; and
the bottom memory die is disposed on the second interposer and the second interposer is disposed on the first interposer.

10. The packaging arrangement of claim 9, further comprising a molding compound over the two LPDDR DRAMs.

11. The packaging arrangement of claim 10, further comprising a heat sink on the molding compound and the SoC die.

12. The packaging arrangement of claim 1, further comprising a molding compound over the stack of memory dies.

13. A packaging arrangement comprising:
a plurality of memory dies stacked on one another to provide a stack of memory dies, wherein each memory die includes input/output (I/O) pads, wherein the I/O pads of a corresponding memory die are located on only one side of the corresponding memory die, wherein the plurality of memory dies is stacked on one another such that all of the I/O pads are arranged along a same side of the stack of memory dies, and wherein the plurality of memory dies is stacked such that all the I/O pads are exposed; and
a molding compound substantially encapsulating the stack of memory dies, wherein the molding compound comprises contacts configured to electrically couple the packaging arrangement to a substrate.

14. The packaging arrangement of claim 13, wherein the I/O pads are coupled to the contacts by one of (i) wirebond connections or (ii) pillars.

15. A packaging arrangement comprising:
an interposer;
a plurality of memory dies stacked on one another to provide a stack of memory dies, wherein a bottom memory die of the stack of memory dies is disposed on the interposer, wherein each memory die includes input/output (I/O) pads, wherein the I/O pads of a corresponding memory die are located on only one side of the corresponding memory die, wherein the plurality of memory dies is stacked on one another such that all of the I/O pads are arranged along a same side of the stack of memory dies, and wherein the plurality of memory dies is stacked such that all the I/O pads are exposed.

16. The packaging arrangement of claim 15, wherein the plurality of memory dies comprises a plurality of low power double data rate synchronous (LPDDR) dynamic random access memory (DRAM) dies.

17. The packaging arrangement of claim 16, wherein the I/O pads are located on top surfaces of the LPDDR DRAMs and the plurality of LPDDR DRAMs are stacked in an offset relationship such that all the I/O pads are exposed.

18. The packaging arrangement of claim 17, wherein the plurality of LPDDR Drams comprises four LPDDR DRAMs.

19. The packaging arrangement of claim 17, wherein the plurality of LPDDR Drams comprises two LPDDR DRAMs.

20. The packaging arrangement of claim 17, further comprising a molding compound over the plurality of LPDDR DRAMs.
